(19) United States
(12) Patent Application Publication
(10) Pub. No.: US 2007/0048677 A1
(43) Pub. Date: Mar. 1, 2007

(54) Exposure method for making separator

(75) Inventor: Chien-Chung Kuo, Taichung County (TW)

Correspondence Address: BACON & THOMAS, PLLC, 625 SLATERS LANE, FOURTH FLOOR, ALEXANDRIA, VA, 22314, US

(73) Assignee: Wintek Corporation, TAICHUNG (TW)

(21) Appl. No.: 11/211,520

(22) Filed: Aug. 26, 2005

(51) Int. Cl. G03F 7/20

(52) U.S. Cl. 430/394; 430/311; 430/322

(57) ABSTRACT

An exposure method for making a separator includes the steps of providing a substrate on which a positive photoresist is coated, providing a mask having a light-transmissible region and a light-blocking region, and performing first-time and second-time exposures respectively sequentially by using UV light obliquely irradiating on the mask with a respective included angle between a surface direction of the mask and an incident direction of the UV light.

### BACKGROUND OF THE INVENTION

1. Field of the Invention

The present invention relates generally to an exposure method of making a separator by a photoresist, and more particularly to an exposure method of making a separator having a reverse tapered cross-section by a positive photoresist.

2. Description of the Related Art

A conventional organic electroluminescence display panel is known comprised of a substrate on which a plurality of first display electrodes (anodes) of a strip shape made of a transparent conductive material such as indium tin oxide (ITO) are formed, a plurality of electrical insulation separators spacedly projecting from the substrate for exposing portions of the first display electrodes respectively, organic layers formed on the exposed portions of the first display electrodes respectively, and a plurality of second display electrodes (cathodes) made of metal and formed on the organic layers. FIG. 1 is a schematic drawing showing a substrate 1 from which a separator 2 having a reverse tapered cross-section projects according to the prior art. It is to be noted that only one separator 2 is shown and the anodes, organic layers and cathodes are not shown in FIG. 1 for easily illustrative purpose. According to this design, the metal cathodes, which are typically made of aluminum, are formed on the tops of the separators and the organic layers by vacuum deposition after the formation of organic layers by depositing organic electroluminescence media on the exposed portions of the anodes respectively. Since the separators having a reverse tapered cross-section with overhanging portions, i.e. the tops of the separators have a width greater than that of the bottoms of the separators, and the metal cathodes are vacuum-deposited on the substrate in such a manner that the metal vapor drops substantially perpendicular to the substrate, no cathode is formed on the position under the overhanging portions of the separators and on the slanted sidewalls of the reverse tapered separators 2, such that the adjacent cathodes, which are separated by the separators, are electrically disconnected to each other.

A conventional method for making the separators is to coat a negative chemically amplified photoresist on the substrate 1 first. And then, the substrate 1 is treated by a series of processes including soft baking, exposure, post exposure baking, development, and hard baking in sequence to form the separators 2 on the substrate 1. As shown in FIG. 2, during the exposure process a UV light 3, which is perpendicularly irradiated to a mask 4, passes through a transmissible region of the mask 4 to a predetermined exposed region 5a of a negative chemically amplified photoresist film 5, such that a cross-linking effect is induced at the exposed region 5a of the negative chemically amplified photoresist film 5. Since the anti-developed ability of the exposed region 5a is gradually decreased from a surface thereof to a bottom side proximal to the substrate 1, an unexposed region 5b of the photoresist film 5 is dissolved and the exposed region 5a is remained to form the separators 2 having a reverse tapered cross-section as shown in FIG. 1 after the development treatment is performed.

The above-mentioned method is extensively used to make the separators in industry; however, the negative chemically amplified photoresist used in the above-mentioned method is expensive compared to other types of photoresist, causing the increase of manufacturing cost of the organic electroluminescence display. In addition, the exposed negative chemically amplified photoresist will absorb partially the development solution in the exposure process (this is so called swelling effect) so that the volume of the photoresist particles will be increased. As a result, the pattern of the photoresist after development is distorted and the slanting degreed of the separator is affected, thereby lowering the yield of products.

### SUMMARY OF THE INVENTION

The primary objective of the present invention is to provide an exposure method of making a separator, which reduces the cost of the photoresist and increases the yield of products.

According to the objective of the present invention, an exposure method for making a separator provided by the present invention includes the steps of:

a) coating a positive photoresist layer on a substrate;

b) providing a mask having a light-transmissible region and a light-blocking region;

c) performing a first-time exposure by using light obliquely irradiating on the mask with a first included angle θ1 between a surface direction of the mask and an incident direction of the light; and

d) performing a second-time exposure by using light obliquely irradiating on the mask with a second included angle θ2 between the surface direction of the mask and an incident direction of the light.

In a preferred embodiment of the present invention, two light paths are arranged at opposite sides of a normal line of the mask to perform respectively the first-time and second-time exposures.

In another preferred embodiment of the present invention, one light path is only used for performing the first-time and second-time exposures.

### BRIEF DESCRIPTION OF THE DRAWINGS

FIG. 1 is a schematic drawing showing a substrate from which a separator having a reverse tapered cross-section projects according to prior art;

FIG. 2 is schematic drawing showing an exposure process for making a separator according to prior art;

FIG. 3 is a schematic drawing showing a mask is provide on the photoresist according to a first preferred embodiment of the present invention;

FIG. 4 is a schematic drawing showing the first-time exposure step according to the first preferred embodiment of the present invention;

FIG. 5 is a schematic drawing showing the photoresist after the first-time exposure step according to the first preferred embodiment of the present invention;

FIG. 6 is a schematic drawing showing the second-time exposure step according to the first preferred embodiment of the present invention;

FIG. 7 is a schematic drawing showing the photoresist after the second-time exposure step according to the first preferred embodiment of the present invention;

FIG. 8 is a schematic drawing showing the photoresist after the development treatment according to first preferred embodiment of the present invention;

FIG. 9 is a schematic drawing showing organic layers and cathodes are sequentially deposited on the substrate with the separators made by the method of the first preferred embodiment of the present invention;

FIG. 10 is a schematic drawing showing the first-time exposure step according to a second preferred embodiment of the present invention;

FIG. 11 is a schematic drawing showing the second-time exposure step according to the second preferred embodiment of the present invention, and

FIG. 12 is a schematic drawing showing the photoresist after the development treatment according to the second preferred embodiment of the present.

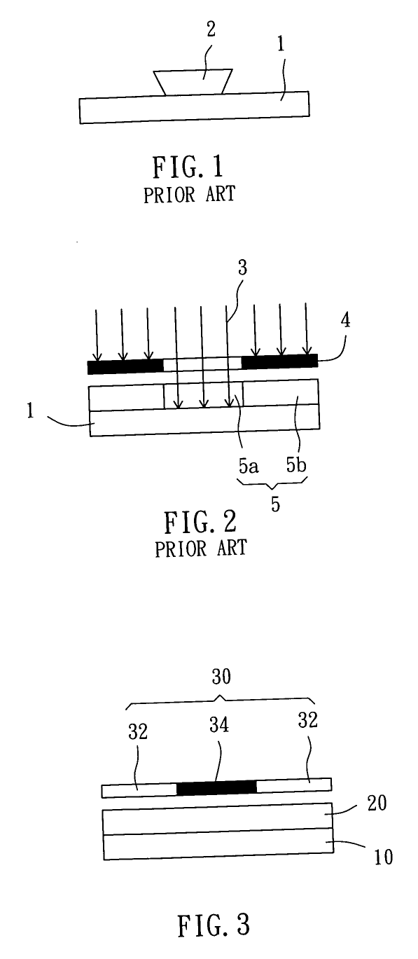

### DETAILED DESCRIPTION OF THE INVENTION

An exposure method of making a separator provided by a first preferred embodiment of the present invention comprises the steps as follows.

As shown in FIG. 3, a liquid state positive photoresist is evenly uniformly coated on a surface of a substrate 10 on which a first display electrodes, e.g. anodes (not shown), have been already patterned by a coating method including spin coating, roller coating and any of well-known methods so as to form a photoresist film 20 on the surface of the substrate 10. And then, the substrate 10 and the photoresist film 20 undergo a soft-baking treatment to enhance the bond between the photoresist 20 and the substrate 10.

The substrate 10 can be made of glass, plastic, ceramics, or can be a substrate on which an electrically conductive film, such as indium tin oxide (ITO) film, indium zinc oxide (IZO) film, etc., is provided. For the positive photoresist, any commercially available positive photoresist materials, such as AZ P4210 (Clariant Corporation), AZ 1500 (Clariant Corporation), ZWD6216 (Zeon Corporation), and DL-1000 (PSPI) (Toray Engineering Co. Ltd.), can be used.

Referring to FIG. 3 again, a mask 30 is then provided above the photoresist film 20. The mask 30 has a light-transmissible region 32 and a light-blocking region 34.

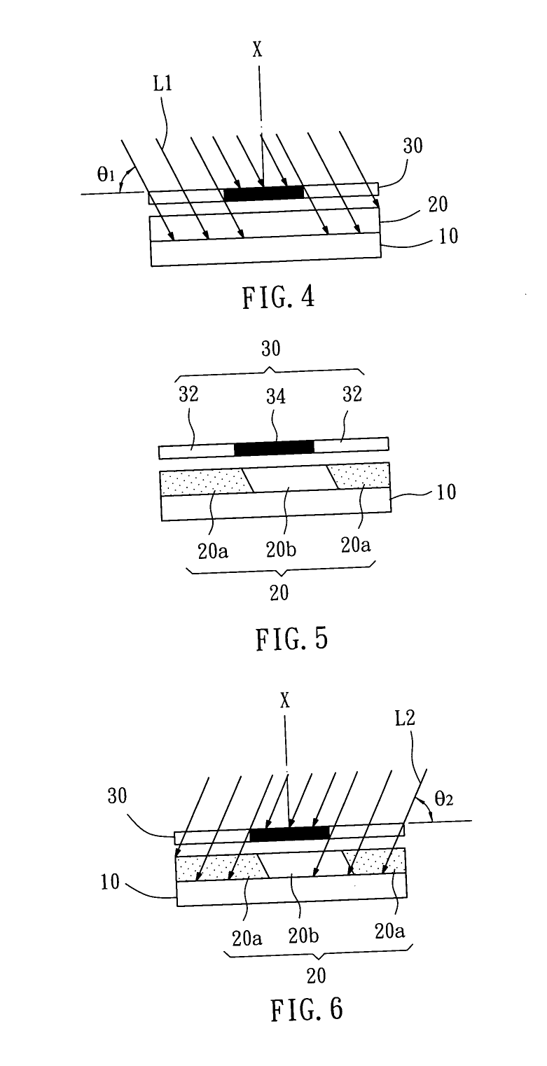

As shown in FIG. 4 and FIG. 5, a first-time exposure is then performed by using light obliquely irradiating on the mask 30 with a first included angle θ1 between a surface direction of the mask 30 and an incident direction L1 of the light. In this preferred embodiment, the light is emitted from an ultraviolet (UV) light source (not shown) spacedly arranged at a left side of a normal line X of the mask 30 and above the mask 30 with a distance. The included angle θ1 is less than 90 degrees, in other words, it is an acute angle. The UV light goes through the light-transmissible region 32 of the mask 30 to the photoresist film 20. A portion 20a exposed under the UV light will be dissolved in a development solution and the other portion 20b which is not exposed will not be dissolved in the development solution during a development process.

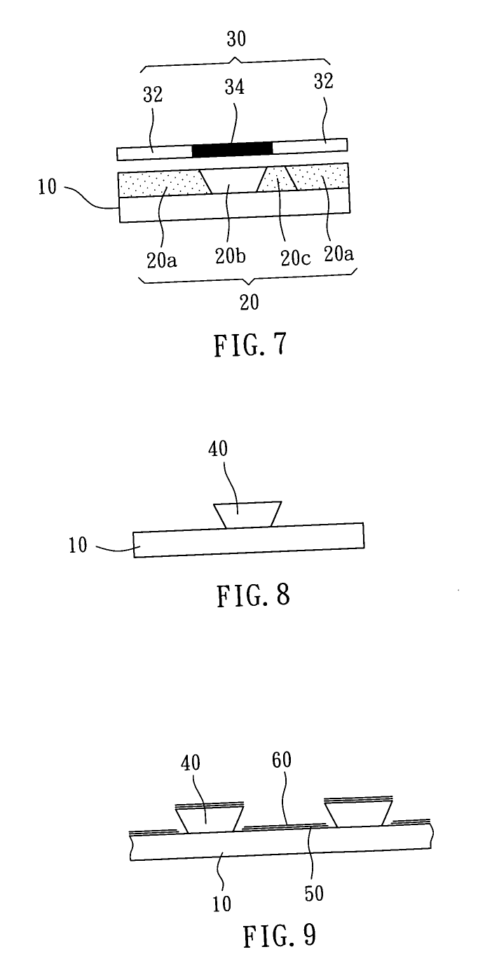

Referring to FIG. 6 and FIG. 7, a second-time exposure is then performed after the first-time exposure by using light obliquely irradiating on the mask 30 with a second included angle θ2 between the surface direction of the mask 30 and an incident direction L2 of the light. The light is also emitted from an ultraviolet (UV) light source (not shown) spacedly arranged at a right side of the normal line X of the mask 30 and above the mask 30 with a distance. The second included angle θ2 is also an acute angle, which has a magnitude equal to that of the first included angle θ1. A region 20c, which is a part of the unexposed region 20b in the first-time exposure, is now exposed under the UV light during the second-time exposure. As a result, the unexposed region 20b has a relatively longer width at a top thereof and a relatively shorter width at a bottom thereof.

A development process will be then performed after the first-time and second-time exposures. During the development process, the photoresist film 20 is dissolved by a development solution, such that the exposed regions 20a and 20c are dissolved but the unexposed region 20b is remained to form a separator 40 having a reverse tapered cross-section with as shown in FIG. 8. In other words, the separator 40 has a relatively longer width at the top thereof, a relatively shorter width at the bottom thereof, and two slanted sidewalls extended respectively from two sides of the top to two sides of the bottom. Slopes of the sidewalls of the separator 40 are determined subject to the included angles θ1 and θ2 between the incident directions L1 and L2 of the UV lights and the surface direction of the mask 30 respectively. In practice, the first included angle θ1 may not be equal to the second included angle θ2.

As shown in FIG. 9, a plurality of organic layers 50 and metal cathodes 60 are sequentially deposited during a series of processes on the substrate 10 having the separators 40 made by the above-mentioned steps of the present invention for constructing an organic electroluminescence display panel.

In the above-mentioned first preferred embodiment, the substrate 10 is stationary and exposed two times by two UV lights with different incident directions L1 and L2, which are respectively sequentially emitted from two different UV light sources spacedly arranged at opposite sides of the normal line of the mask 30. However, the first-time and second-time exposures can be achieved by using only one UV light source with the rotation of the substrate as follows.

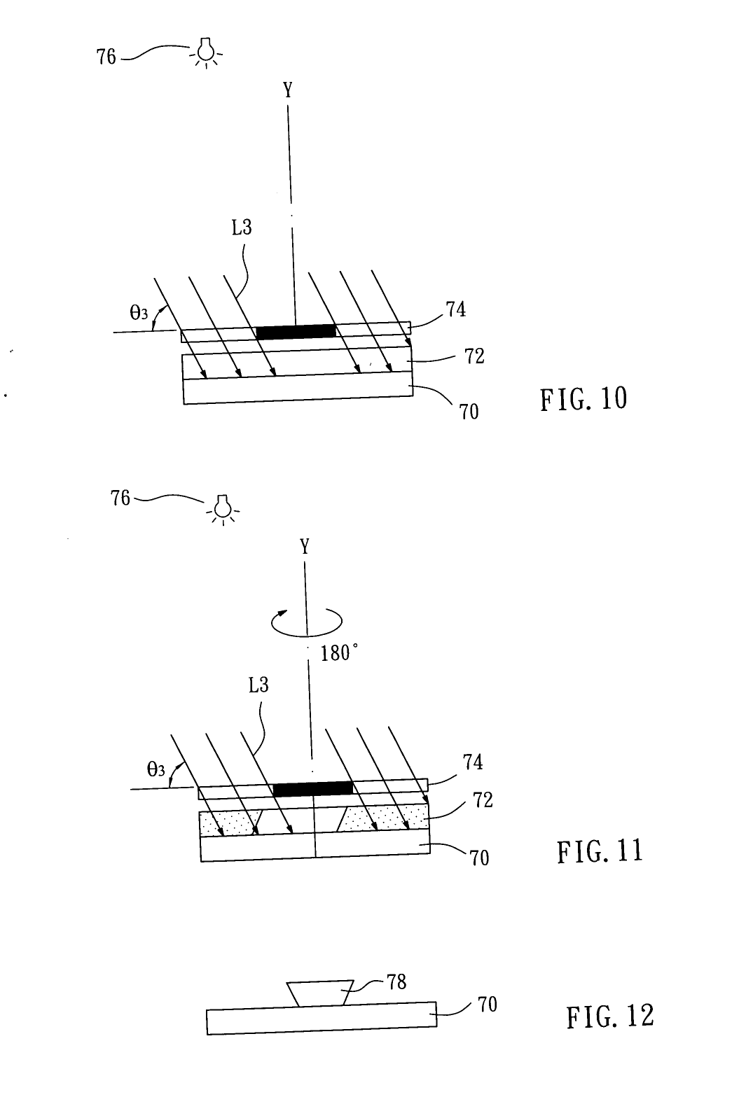

As shown in FIG. 10, a first-time exposure is performed by using UV light obliquely irradiating on a mask 74, which is set above a substrate 70 on which a positive photoresist film 72 is coated, with a third included angle θ3 between a surface direction of the mask 74 and an incident direction L3 of the UV light. In this preferred embodiment, the UV light is emitted from an ultraviolet (UV) light source 76 spacedly arranged at a left side of a normal line Y of the mask 74 and above the mask 74 with a distance. The included angle θ3 is also an acute angle. In addition, the substrate 70 is supported on a turntable (not shown), so that the substrate 70 is rotatable about the normal line Y.

After the first-time exposure, the substrate 70 is rotated 180 degrees about the normal liner Y as shown in FIG. 11, and then the second-time exposure is carried out by using the same UV light source 76. After the second-time exposure, the photoresist 72 is washed by a development solution to have a separator 78 on the substrate 70, as shown in FIG. 12.

In the above-mentioned preferred embodiments, the light source used in the exposure proceeding for irradiating the UV light is obliquely arranged above the mask. However, the location of the light source is not limited to such place disclosed in the above-mentioned embodiments. For example, by means of an optical lens set that can change the path of light by refraction the light source can be placed anywhere to have the incident light obliquely irradiate on the mask with a predetermined included angle so as to achieve the exposure proceeding.

In conclusion, the method of the present invention uses the commercially available positive photoresist, which is cheaper than the negative chemically amplified photoresist, to form the separators, thereby lowering the manufacturing cost. In addition, the positive photoresist has a less expansion degree compared to the negative photoresist while washed by the development solution. As a result, the separators made by the method of the present invention have a smaller degree of deformation and a higher yield.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. An exposure method for making a separator, comprising the steps of:
a) coating a positive photoresist layer on a substrate;
b) providing a mask having a light-transmissible region and a light-blocking region on the positive photoresist;
c) performing a first-time exposure by using light obliquely irradiating on the mask with a first included angle θ1 between a surface direction of the mask and an incident direction of the light; wherein the light passes through the light-transmissible region of the mask to the positive photoresist; and
d) performing a second-time exposure by using light obliquely irradiating on the mask with a second included angle θ2 between the surface direction of the mask and an incident direction of the light.

2. The exposure method as defined in claim 1, wherein in the step c) the light is emitted from a light source spacedly arranged at a side of a normal line of the mask on the mask, and in the step d) the light is emitted from another light source spacedly arranged at an opposite side of the normal line of the mask on the mask.

3. The exposure method as defined in claim 1, wherein the first included angle θ1 has a magnitude substantially equal to that of the second included angle θ2.

4. The exposure method as defined in claim 1, wherein the positive photoresist is selected from a group consisting of AZ P4210 (Clariant Corporation), AZ 1500 (Clariant Corporation), ZWD6216 (Zeon Corporation), and DL-1000 (PSPI) Toray Engineering Co. Ltd.).

5. The exposure method as defined in claim 1, wherein in the step c) the light obliquely irradiating on the mask is an ultraviolet light.

6. The exposure method as defined in claim 1, wherein in the step d) the light obliquely irradiating on the mask is an ultraviolet light.

7. The exposure method as defined in claim 1, wherein the substrate is selected from a group consisting of a glass substrate, plastic substrate, ceramic substrate, and a substrate with an electrically conductive film.

8. The exposure method as defined in claim 1, wherein the first included angle θ1 is less than 90 degrees.

9. The exposure method as defined in claim 1, wherein the second included angle θ2 is less than 90 degrees.

10. An exposure method for making a separator, comprising the steps of:
a) coating a positive photoresist layer on a substrate;
b) providing a mask having a light-transmissible region and a light-blocking region;
c) performing a first-time exposure by using light obliquely irradiating on the mask with an included angle between a surface direction of the mask and an incident direction of the light;
d) rotating the substrate about a normal line of the mask with a predetermined angle; and
e) performing a second-time exposure by using the light; defined in the step c), obliquely streaming on the mask.

11. The exposure method as defined in claim 10, wherein in the step d) the substrate is rotated 180 degrees about the normal line of the mask.

12. The exposure method as defined in claim 10, wherein the positive photoresist is selected from a group consisting of AZ P4210 (Clariant Corporation), AZ 1500 (Clariant Corporation), ZWD6216 (Zeon Corporation), and DL-1000 (PSPI) (Toray Engineering Co. Ltd.).

13. The exposure method as defined in claim 10, wherein the substrate is selected from a group consisting of a glass substrate, plastic substrate, ceramic substrate, and a substrate with an electrically conductive film.

14. The exposure method as defined in claim 10, wherein the included angle is less than 90 degrees.

15. The exposure method as defined in claim 10, wherein in the step c) the light obliquely irradiating on the mask is an ultraviolet light.

16. An organic electroluminescence display panel comprising a substrate from which a plurality of separators, which undergo an exposure method defined in claim 1, project.

17. An organic electroluminescence display panel comprising a substrate from which a plurality of separators, which undergo an exposure method defined in claim 10, project.
